(19) United States
(12) Patent Application Publication
(10) Pub. No.: US 2023/0180527 A1
(43) Pub. Date: Jun. 8, 2023

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Chao YANG, Beijing (CN); Pohsien WU, Beijing (CN)

(21) Appl. No.: 17/921,903

(22) PCT Filed: May 20, 2021
(86) PCT No.: PCT/CN2021/094919

§ 371 Date: Oct. 27, 2022

(30) Foreign Application Priority Data
Jun. 2, 2020 (CN) 202010489284.0

(51) Int. Cl. H10K 59/122; H10K 59/173; H10K 59/80

(52) U.S. Cl. CPC H10K 59/122; H10K 59/173; H10K 59/80515; H10K 59/80521; H10K 59/35

(57) ABSTRACT

Provided are a display substrate and a display apparatus. The display substrate includes: a base substrate, and a first electrode layer, a barrier layer and a common layer, which are sequentially located on one side of the base substrate, wherein the first electrode layer includes a plurality of first electrodes located in sub-pixel areas; the barrier layer includes a plurality of barrier portions used for defining the sub-pixel areas; the common layer covers the barrier portions and the first electrodes; a barrier portion located between two sub-pixel areas which are at least partially adjacent is provided with at least one first recessed structure; and the common layer is provided with a second recessed structure in an area corresponding to the first recessed structure.

### CROSS REFERENCE TO RELATED APPLICATIONS

The present disclosure claims the benefit of priority to Chinese Patent Application No. 202010489284.0, filed to the China Patent Office on Jun. 2, 2020 and entitled “DISPLAY PANEL AND DISPLAY APPARATUS”, which is incorporated in its entirety herein by reference.

### FIELD

The present disclosure relates to the field of display, and in particular to a display substrate and a display apparatus.

### BACKGROUND

On account of thinness, lightness, flexibility and wide viewing angle, the organic light-emitting diode (OLED) display technology has gained widespread concern.

However, an OLED display substrate in the related art has a problem that sub-pixels of other colors are slightly bright when a red, green or blue (R, G or B) single-color picture is displayed.

### SUMMARY

An embodiment of the present disclosure provides a display substrate. The display substrate includes: a base substrate divided into a plurality of sub-pixel areas; a first electrode layer located on one side of the base substrate, where the first electrode layer includes a plurality of first electrodes located in the plurality of sub-pixel areas; a barrier layer located on one side of the first electrode layer that faces away from the base substrate, where the barrier layer includes a plurality of barrier portions configured for defining the plurality of sub-pixel areas, and the barrier portion located between two sub-pixel areas that are at least partially adjacent to each other is provided with at least one first recessed structure; and a common layer located on one side of the barrier layer that faces away from the base substrate, where the common layer covers the plurality of barrier portions and the first electrodes, and the common layer is provided with at least one second recessed structure in an area corresponding to the at least one first recessed structure.

In a possible implementation, in the above display substrate provided in an embodiment of the present disclosure, the barrier layer includes a pixel definition layer and/or a spacer layer.

In a possible implementation, in the above display substrate provided in an embodiment of the present disclosure, the barrier portion located between two adjacent sub-pixel areas emitting light of different colors is provided with at least one first recessed structure.

In a possible implementation, in the above display substrate provided in an embodiment of the present disclosure, the barrier portion located between two adjacent sub-pixel areas emitting light of the same color is provided with at least one first recessed structure.

In a possible implementation, in the above display substrate provided in an embodiment of the present disclosure, a distance between a bottom end face of the first recessed structure and a first surface is greater than or equal to a distance between a surface of each first electrode that faces away from the base substrate and the first surface, and the first surface is a surface of the base substrate that faces the plurality of first electrodes.

In a possible implementation, in the above display substrate provided in an embodiment of the present disclosure, the barrier portion located between the two sub-pixel areas that are at least partially adjacent to each other is provided with a plurality of first recessed structures, and the plurality of first recessed structures have the same depth.

In a possible implementation, in the above display substrate provided in an embodiment of the present disclosure, the barrier portion located between the two sub-pixel areas that are at least partially adjacent to each other is provided with a plurality of first recessed structures, and the plurality of first recessed structures have the same shape.

In a possible implementation, in the above display substrate provided in an embodiment of the present disclosure, the barrier portion located between the two sub-pixel areas that are at least partially adjacent to each other is provided with a plurality of first recessed structures, and the plurality of first recessed structures are arranged in a staggered manner in a direction of a connecting line between the two sub-pixel areas.

In a possible implementation, the above display substrate provided in an embodiment of the present disclosure further includes: a light-emitting layer located on the one side of the barrier layer that faces away from the base substrate.

The common layer includes a first common layer located between the light-emitting layer and the barrier layer, and a second common layer located on one side of the light-emitting layer that faces away from the base substrate.

In a possible implementation, in the above display substrate provided in an embodiment of the present disclosure, the plurality of first electrodes are anodes; and the first common layer includes a hole injection layer and/or a hole transport layer; and the second common layer includes an electron injection layer and/or an electron transport layer.

In a possible implementation, the above display substrate provided in an embodiment of the present disclosure further includes: a second electrode layer located on one side of the common layer that faces away from the base substrate.

The second electrode layer is provided with a third recessed structure at a position corresponding to the second recessed structure.

An embodiment of the present disclosure further provides a display apparatus. The display apparatus includes the display substrate provided in an embodiment of the present disclosure.

### BRIEF DESCRIPTION OF THE DRAWINGS

FIG. 1 is a schematic diagram of crosstalk generation in the related art.

FIG. 2 is another schematic diagram of crosstalk generation in the related art.

FIG. 3 is a schematic structural diagram of a section of a display substrate at a gap between pixels of different colors according to an embodiment of the present disclosure.

FIG. 4 is a schematic structural diagram in a top view of a display substrate according to an embodiment of the present disclosure.

FIG. 5 is a schematic structural diagram of a section of a display substrate at a position of a spacer according to an embodiment of the present disclosure.

### DETAILED DESCRIPTION OF THE EMBODIMENTS

In order to make the objectives, technical solutions and advantages of the embodiments of the present disclosure clearer, the technical solutions of the embodiments of the present disclosure will be clearly and completely described below in combination with the accompanying drawings in the embodiments of the present disclosure. Obviously, the embodiments described are merely some rather than all of the embodiments of the present disclosure. On the basis of the described embodiments of the present disclosure, all other embodiments obtained by those of ordinary skill in the art without making inventive efforts fall within the scope of protection of the present disclosure.

Unless otherwise defined, technical terms or scientific terms used in the present disclosure should have ordinary meanings understood by those with ordinary skills in the field to which the present disclosure belongs. Words “first”, “second”, etc. used in the present disclosure do not denote any order, quantity or importance, but are merely used to distinguish between different components. Word “include”, “contain” or the like is intended to mean that an element or item in front of the word encompasses elements or items that present behind the word and equivalents thereof, but does not exclude other elements or items. Word “connect”, “connected” or the like is not limited to physical or mechanical connections, but may include electrical connections, whether direct or indirect. “Upper”, “lower”, “left”, “right”, etc. are merely used to indicate a relative position relation, which may change accordingly when an absolute position of a described object changes.

In order to keep the following description of the embodiments of the present disclosure clear and concise, the detailed descriptions of known functions and components are omitted from the present disclosure.

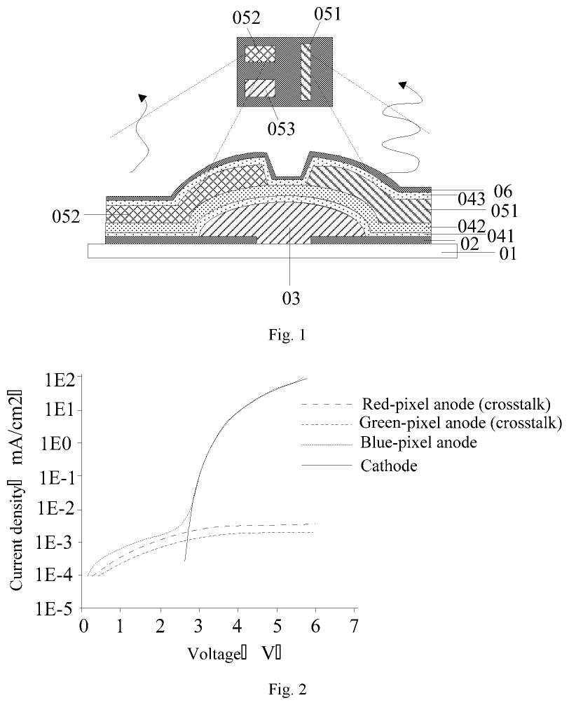

In the related art, with reference to FIGS. 1 and 2, an organic light-emitting diode (OLED) display substrate includes an anode 02, a pixel definition layer 03, a hole injection layer 041, a hole transport layer 042, an organic light-emitting layer (including a blue light-emitting portion 051, a red light-emitting portion 052 and a green light-emitting portion 053), an electron injection layer 043 and a cathode layer 06, which are sequentially located on one side of a base substrate 01. The electron injection layer 043 and the hole injection layer 041 are arranged on an upper side and a lower side of the organic light-emitting layer respectively. When a current flows through the organic light-emitting layer, the organic light-emitting layer emits light. The hole injection layer 041 and the hole transport layer 042 below are generally connected in series by means of a common layer. When pixels per inch (PPI) of a screen body are greater than 300, a distance between two pixels will become extremely small. In a turning-on process, a current will arrive at the adjacent pixels by means of the common layer, resulting in a defect of a transverse crosstalk, that is, as shown in FIG. 2, sub-pixels of other colors are slightly bright when the screen body in a red, green or blue (R, G or B) single-color picture.

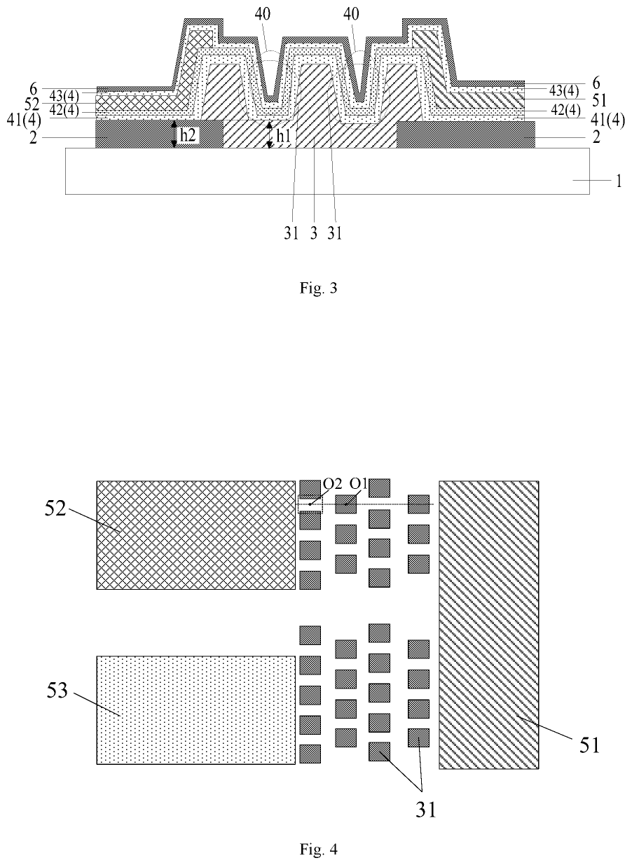

In view of this, with reference to FIGS. 3 and 4, an embodiment of the present disclosure provides a display substrate. The display substrate includes: a base substrate 1 divided into a plurality of sub-pixel areas; a first electrode layer located on one side of the base substrate 1, where the first electrode layer includes a plurality of first electrodes 2 located in the sub-pixel areas, and the plurality of first electrodes 2 are independent from each other and arranged at intervals; a barrier layer located on one side of the first electrode layer that faces away from the base substrate 1, where the barrier layer includes a plurality of barrier portions 3 used for defining the sub-pixel areas, it can be considered that at least one barrier portion 3 is arranged between every two adjacent sub-pixel areas, an area delimited by a plurality of barrier portions 3 connected end to end is a sub-pixel area, the barrier portion located between two adjacent sub-pixel areas that are at least partially adjacent to each other is provided with at least one first recessed structure 31, for example, the barrier portion 3 located between two adjacent sub-pixel areas emitting light of different colors (for example, between the sub-pixel area emitting blue light and the sub-pixel area emitting red light, or between the sub-pixel area emitting blue light and the sub-pixel area emitting green light) is provided with at least one first recessed structure 31, for another example, the barrier portion 3 located between two adjacent sub-pixel areas emitting light of the same color (for example, between the sub-pixel areas emitting blue light) is provided with at least one first recessed structure 31, or each barrier portion 3 is provided with at least one first recessed structure 31, which is not limited herein; and a common layer 4 located on one side of the barrier layer that faces away from the base substrate, where the common layer 4 covers the barrier portions 3 and the first electrodes 2, and the common layer 4 is provided with a second recessed structure 40 in an area corresponding to the first recessed structure 31.

According to the display substrate in an embodiment of the present disclosure, by arranging at least one first recessed structure on the barrier portion, the common layer may be provided with a corresponding second recessed structure at a position corresponding to the first recessed structure, such that the common layer is in a curved non-planar shape. Without influencing a pixel design, by converting direct lap joint of the common layer into a geometric design, a length of the common layer may be increased, and a current inflow path of the common layer may be prolonged, so as to increase impedance between the sub-pixel areas, thereby reducing a current flowing to the adjacent sub-pixel areas when one sub-pixel area is driven to emit light, and further reducing an influence of a transverse crosstalk on the adjacent sub-pixel areas.

During specific implementation, with reference to FIG. 3, the above display substrate provided in an embodiment of the present disclosure may further include: a light-emitting layer located on one side of the barrier layer that faces away from the base substrate 1. The light-emitting layer may specifically include a plurality of light-emitting portions located in the sub-pixel areas, for example, a red light-emitting portion 52 located in a red sub-pixel area, a green light-emitting portion 53 located in a green sub-pixel area, and a blue light-emitting portion 51 located in a blue sub-pixel area, and the light-emitting portions of different colors are arranged at intervals. Correspondingly, the common layer 4 may include a first common layer located between the light-emitting layer and the barrier layer, and a second common layer located on one side of the light-emitting layer that faces away from the base substrate.

Moreover, with reference to FIG. 3, the above display substrate provided in an embodiment of the present disclosure may further include: a second electrode layer 6 located on one side of the common layer that faces away from the base substrate 1. Correspondingly, the second electrode layer 6 is provided with a third recessed structure at a position corresponding to the second recessed structure 40, that is, the second electrode layer 6 is correspondingly recessed at a position of the second recessed structure 40 to form the third recessed structure.

Specifically, the first electrodes 2 may be anodes and the second electrode layer 6 may be a cathode layer, the first common layer may include a hole injection layer 41 and/or a hole transport layer 42, and the second common layer may include an electron injection layer (not shown in the figure) and/or an electron transport layer 43; or conversely, i.e., the first electrodes 2 may be cathodes and the second electrode layer 6 may be an anode, the second common layer may include a hole injection layer and/or a hole transport layer, and the first common layer may include an electron injection layer and/or an electron transport layer. In the case that the first common layer includes the hole injection layer 41 and the hole transport layer 42, the hole transport layer 42 may be located on one side of the hole injection layer 41 that faces away from the anodes. In the case that the second common layer includes the electron injection layer and the electron transport layer 43, the electron transport layer 43 is located on one side of the electron injection layer that faces away from cathodes.

During specific implementation, the barrier layer in the above display substrate provided in an embodiment of the present disclosure may include a pixel definition layer and/or a spacer layer. That is, the first recessed structure may be only formed on the pixel definition layer, the first recessed structure may be only formed on the spacer layer, or the first recessed structures may be formed on the pixel definition layer and the spacer layer.

Specifically, for example, with reference to FIGS. 3 and 4, an isolation layer is a pixel definition layer (PDL). That is, the pixel definition layer is provided with a plurality of barrier portions 3 used for defining the sub-pixel areas, and by digging holes in the barrier portions 3 between the sub-pixel areas, the first recessed structures 31 are formed, such that the above common layer (for example, the hole injection layer 41 and the hole transport layer 42) is correspondingly recessed at positions corresponding to the first recessed structures 31 to form the second recessed structures 40, so as to prolong a transmission path of a current at this position, and solve the problem that when only the sub-pixel area of one color (for example, the blue sub-pixel area) in the display substrate is turned on, the sub-pixel areas of other colors (for example, the red sub-pixel area) are also turned on.

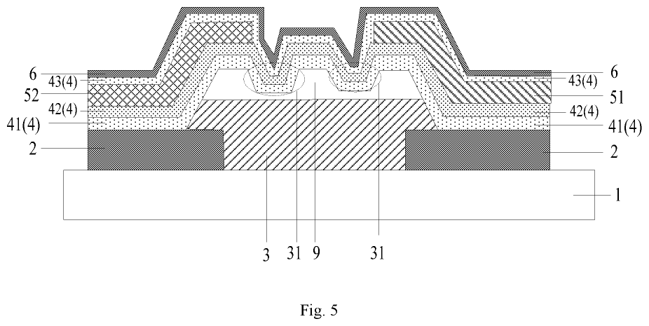

For another example, with reference to FIG. 5, in the display substrate, the barrier portions 3 between the sub-pixel areas are provided the first recessed structures 31, and in addition, a position where the spacer 9 is located may also be provided with a first recessed structure 31, so as to further prolong a transmission path of a current between two adjacent pixels of different colors. It should be noted that FIG. 5 is a schematic structural diagram of a section of a position where the spacer 9 is located, such that a first recessed structure 31 of a barrier portion 3 of the pixel definition layer at this position is not shown.

During specific implementation, in the above display substrate provided in an embodiment of the present disclosure, the barrier portion 3 located between two adjacent sub-pixel areas that are at least partially adjacent to each other may be provided with a plurality of first recessed structures 31, and the plurality of first recessed structures 31 may have the same depth. Setting the depths of the plurality of first recessed structures 31 to be the same may simplify a difficulty of making each first recessed structure 31.

During specific implementation, in the above display substrate provided in an embodiment of the present disclosure, the plurality of first recessed structures 31 may be set in the same shape. For example, an orthographic projection of the first recess structure 31 on the base substrate 1 may be in a circular, square, rectangular or triangular shape, etc.

During specific implementation, in the above display substrate provided in an embodiment of the present disclosure, the plurality of first recessed structures 31 may be arranged in a staggered manner in a direction of a connecting line between two sub-pixel areas, and recessed and raised structures may be provided at any position of the connecting line between the two adjacent sub-pixel areas, so as to prolong a charge transfer path at each position. With reference to FIG. 4, the plurality of first recessed structures 31 between two adjacent sub-pixel areas are distributed in a plurality of rows, and a gap is formed between two adjacent first recessed structures 31 in the same row. A center O1 of any first recessed structure 31 in any column and a center O2 of a gap in an adjacent column are located on the same straight line, that is, the first recessed structures 31 in adjacent columns are arranged in a staggered manner. As shown in FIG. 4, the first recessed structure 31 in a second column from the left corresponds to a gap between the first recessed structures 31 in a first column from the left such that recessed and raised structures any be provided at any position of the connecting line between two adjacent sub-pixel areas emitting light of different colors, so as to prolong a charge transfer path at each position.

During specific implementation, in the above display substrate provided in an embodiment of the present disclosure, as shown in FIG. 3, a distance h1 between a bottom end face of the first recessed structure 31 and a first surface may be greater than or equal to a distance h2 between a surface of the first electrode 2 that faces away from the base substrate 1 and the first surface, and the first surface is a surface of the base substrate 2 that faces the first electrode (in FIG. 3, an example in which the distance h1 between the bottom end face of the first recessed structure 31 and the first surface is equal to the distance h2 between the surface of the first electrode 2 that faces away from the base substrate 1 and the first surface is taken for description, and the present disclosure is not limited thereto). In an embodiment of the present disclosure, the distance between the bottom end face of the first recessed structure and the first surface is greater than or equal to the distance between the surface of the first electrode that faces away from the base substrate and the first surface. That is, when the barrier portion 3 is perforated to form the first recessed structure 31, the bottom end face for perforation should be kept located above an upper surface of the first electrode 2, so as to prevent a situation that due to over deep perforation, the subsequently formed second electrode layer 6 is close to the first electrode 2, such that a risk of a short circuit is likely to occur.

On the basis of the same inventive concept, an embodiment of the present disclosure further provides a display apparatus. The display apparatus includes the display substrate provided in an embodiment of the present disclosure.

According to the display substrate and the display apparatus provided in embodiments of the present disclosure, by arranging at least one first recessed structure at a barrier portion between two sub-pixel areas that are at least partially adjacent to each other, the common layer may be provided with a corresponding second recessed structure at a position corresponding to the first recessed structure, such that the common layer is in a curved non-planar shape. Without influencing a pixel design, by converting direct lap joint of the common layer into a geometric design, a length of the common layer may be increased, and a current inflow path of the common layer may be prolonged, so as to increase impedance between the sub-pixel areas, thereby reducing a current flowing to the adjacent sub-pixel areas when one sub-pixel area is driven to emit light, and further reducing an influence of a transverse crosstalk on the adjacent sub-pixel areas.

Obviously, those skilled in the art can make various amendments and variations to the present disclosure without departing from the spirit and scope of the present disclosure. In this way, if these amendments and variations of the present disclosure fall within the scope of the claims of the present disclosure and equivalent technologies thereof, the present disclosure is further intended to include these amendments and variations.

1. A display substrate, comprising:
a base substrate divided into a plurality of sub-pixel areas;
a first electrode layer located on one side of the base substrate, wherein the first electrode layer comprises a plurality of first electrodes located in the plurality of sub-pixel areas;
a barrier layer located on one side of the first electrode layer facing away from the base substrate, wherein the barrier layer comprises a plurality of barrier portions configured for defining the plurality of sub-pixel areas, and a barrier portion located between two sub-pixel areas is provided with at least one first recessed structure, wherein the two sub-pixel areas are at least partially adjacent to each other; and
a common layer located on one side of the barrier layer facing away from the base substrate, wherein the common layer covers the plurality of barrier portions and the plurality of first electrodes, and the common layer is provided with at least one second recessed structure in an area corresponding to the at least one first recessed structure.

2. The display substrate according to claim 1, wherein the barrier layer comprises a pixel definition layer and/or a spacer layer.

3. The display substrate according to claim 1, wherein a barrier portion located between two adjacent sub-pixel areas emitting light of different colors is provided with at least one first recessed structure.

4. The display substrate according to claim 1, wherein a barrier portion located between two adjacent sub-pixel areas emitting light of a same color is provided with at least one first recessed structure.

5. The display substrate according to claim 1, wherein a distance between a bottom end face of the first recessed structure and a first surface is greater than or equal to a distance between a surface of each first electrode facing away from the base substrate and the first surface, and the first surface is a surface of the base substrate facing the plurality of first electrodes.

6. The display substrate according to claim 1, wherein the barrier portion located between the two sub-pixel areas that are at least partially adjacent to each other is provided with a plurality of first recessed structures, and the plurality of first recessed structures have a same depth.

7. The display substrate according to claim 1, wherein the barrier portion located between the two sub-pixel areas that are at least partially adjacent to each other is provided with a plurality of first recessed structures, and the plurality of first recessed structures have a same shape.

8. The display substrate according to claim 1, wherein the barrier portion located between the two sub-pixel areas that are at least partially adjacent to each other is provided with a plurality of first recessed structures, and the plurality of first recessed structures are arranged in a staggered manner in a direction of a connecting line between the two sub-pixel areas.

9. The display substrate according to claim 1, further comprising: a light-emitting layer located on the one side of the barrier layer facing away from the base substrate; wherein
the common layer comprises a first common layer located between the light-emitting layer and the barrier layer, and a second common layer located on one side of the light-emitting layer facing away from the base substrate.

10. The display substrate according to claim 9, wherein the plurality of first electrodes are anodes;
the first common layer comprises a hole injection layer and/or a hole transport layer; and
the second common layer comprises an electron injection layer and/or an electron transport layer.

11. The display substrate according to claim 1, further comprising: a second electrode layer located on one side of the common layer facing away from the base substrate; wherein
the second electrode layer is provided with a third recessed structure at a position corresponding to the second recessed structure.

12. A display apparatus, comprising a display substrate, wherein the display substrate comprises:
a base substrate divided into a plurality of sub-pixel areas;
a first electrode layer located on one side of the base substrate, wherein the first electrode layer comprises a plurality of first electrodes located in the plurality of sub-pixel areas;
a barrier layer located on one side of the first electrode layer facing away from the base substrate, wherein the barrier layer comprises a plurality of barrier portions configured for defining the plurality of sub-pixel areas, and a barrier portion located between two sub-pixel areas is provided with at least one first recessed structure, wherein the two sub-pixel areas are at least partially adjacent to each other; and
a common layer located on one side of the barrier layer facing away from the base substrate, wherein the common layer covers the plurality of barrier portions and the plurality of first electrodes, and the common layer is provided with at least one second recessed structure in an area corresponding to the at least one first recessed structure.

13. The display apparatus according to claim 12, wherein the barrier layer comprises a pixel definition layer and/or a spacer layer.

14. The display apparatus according to claim 12, wherein a barrier portion located between two adjacent sub-pixel areas emitting light of different colors is provided with at least one first recessed structure.

15. The display apparatus according to claim 12, wherein a barrier portion located between two adjacent sub-pixel areas emitting light of a same color is provided with at least one first recessed structure.

16. The display apparatus according to claim 12, wherein a distance between a bottom end face of the first recessed structure and a first surface is greater than or equal to a distance between a surface of each first electrode facing away from the base substrate and the first surface, and the first surface is a surface of the base substrate facing the plurality of first electrodes.

17. The display apparatus according to claim 12, wherein the barrier portion located between the two sub-pixel areas that are at least partially adjacent to each other is provided with a plurality of first recessed structures, and the plurality of first recessed structures have a same depth.

18. The display apparatus according to claim 12, wherein the barrier portion located between the two sub-pixel areas that are at least partially adjacent to each other is provided with a plurality of first recessed structures, and the plurality of first recessed structures have a same shape.

19. The display apparatus according to claim 12, wherein the barrier portion located between the two sub-pixel areas that are at least partially adjacent to each other is provided with a plurality of first recessed structures, and the plurality of first recessed structures are arranged in a staggered manner in a direction of a connecting line between the two sub-pixel areas.

20. The display apparatus according to claim 12, wherein the display substrate further comprises: a light-emitting layer located on the one side of the barrier layer facing away from the base substrate; wherein
the common layer comprises a first common layer located between the light-emitting layer and the barrier layer, and a second common layer located on one side of the light-emitting layer facing away from the base substrate.
